(19) United States
(12) Patent Application Publication
(10) Pub. No.: US 2007/0223068 A1
(43) Pub. Date: Sep. 27, 2007

(54) Image forming apparatus, image display apparatus, image forming method, image display method, image display system, and storage medium

(76) Inventors: Yukinori Ishii, Kanagawa (JP); Satoru Sugishita, Tokyo (JP); Yasuhiro Hattori, Kanagawa (JP); Yoshiko Aono, Kanagawa (JP)

Correspondence Address: COOPER & DUNHAM, LLP, 1185 AVENUE OF THE AMERICAS, NEW YORK, NY, 10036, US

(21) Appl. No.: 11/717,809

(22) Filed: Mar. 13, 2007

(30) Foreign Application Priority Data
Mar. 23, 2006 (JP) 2006-081521

(51) Int. Cl. G03F 3/10

(52) U.S. Cl. 358/527

(57) ABSTRACT

A disclosed image forming apparatus includes a display unit information obtaining unit configured to obtain display unit information regarding a display unit; and a display image generating unit configured to generate a display image to be displayed on the display unit based on the display unit information obtained by the display unit information obtaining unit.

### BACKGROUND OF THE INVENTION

1. Field of the Invention

The present invention generally relates to an image forming apparatus, an image display apparatus, an image forming method, an image display method, an image display system, and a storage medium.

2. Description of the Related Art

There is an image forming apparatus having a function to preview an image on a display apparatus such as an operations panel before forming the image on a recording medium such as paper. In such an image forming apparatus, to quickly display a preview image on the display apparatus, it is necessary to reduce the time needed to generate the preview image and the time needed to transfer the preview image to the display apparatus.

A print control apparatus disclosed in patent document 1 generates intermediate print data and a preview image from image data when the image data are registered and stores the intermediate print data and the preview image. The intermediate print data and the preview image are linked with the image data. When receiving a print command to print the image data on a recording medium such as paper, the disclosed print control apparatus retrieves the intermediate print data and the preview image and displays the preview image. Thus, the disclosed print control apparatus is configured to reduce the time needed to display a preview image.

An image forming apparatus disclosed in patent document 2 includes two control units, one for controlling an operations panel and one for controlling a preview screen (preview screen control unit). This configuration makes it possible to operate the operations panel even while a preview image is being transferred to the preview screen.

[Patent document 1] Japanese Patent Application Publication No. 2003-216373

[Patent document 2] Japanese Patent Application Publication No. 2005-208315

Meanwhile, there is an image forming apparatus (hereafter called image forming apparatus A for descriptive purposes) equipped with multiple operations panels having different functions. A user can select any one of the multiple operations panels and connect the selected operations panel to the image forming apparatus A. The image forming apparatus A is designed to meet various requests from users while reducing the production and development costs. One disadvantage of the image forming apparatus A is that it is necessary to generate various types of preview images that suit various operations panels or other display apparatuses.

Also, there is an image forming apparatus (hereafter called image forming apparatus B for descriptive purposes) having a communication function that enables entering a command (for example, a command to output an image) from, for example, a personal computer or a PDA connected via a network. The image forming apparatus B sends a preview image to the display apparatus of the personal computer or the PDA from which the command is sent. Therefore, the image forming apparatus B has to generate a preview image according to the capabilities or specifications of the display apparatus of the personal computer or the PDA. Also, the data size of the preview image must be determined taking into account the speed of communication between the image forming apparatus B and the display apparatus.

Take, for example, a case where the technology disclosed in patent document 1 is applied to the image forming apparatuses A and B as described above. In this case, the data size and the number of types of preview images increase greatly and it becomes difficult to generate and store preview images for all operations panels or display apparatuses having different capabilities or specifications.

Also, take a case where the technology disclosed in patent document 2 is applied to the image forming apparatuses A and B. In this case, it is impractical to provide preview screen control units for all operations panels or display apparatuses having different capabilities or specifications.

### SUMMARY OF THE INVENTION

The present invention provides an image forming apparatus, an image display apparatus, an image forming method, an image display method, an image display system, and a storage medium that substantially obviate one or more problems caused by the limitations and disadvantages of the related art.

Embodiments of the present invention provide an image forming apparatus, an image display apparatus, an image forming method, an image display method, an image display system, and a storage medium that make it possible to generate an appropriate preview image of image data for any one of display apparatuses having different capabilities or specifications or connected in different manners.

An embodiment of the present invention provides an image forming apparatus including a display unit information obtaining unit configured to obtain display unit information regarding a display unit; and a display image generating unit configured to generate a display image to be displayed on the display unit based on the display unit information obtained by the display unit information obtaining unit.

Another embodiment of the present invention provides an image forming apparatus including a communication unit configured to communicate with a remote display unit; a remote display unit information obtaining unit configured to obtain remote display unit information regarding the remote display unit via the communication unit; and a remote display image generating unit configured to generate a display image to be displayed on the remote display unit based on the remote display unit information obtained by the remote display unit information obtaining unit.

Another embodiment of the present invention provides an image display apparatus including a display unit configured to display a display image output from an image forming apparatus; a communication unit configured to communicate with the image forming apparatus; a display unit information retaining unit configured to retain display unit information regarding the display unit; and a display unit information output unit configured to output the display unit information retained by the display unit information retaining unit; wherein the display unit information includes resolution of the display unit or a number of colors displayable by the display unit.

Another embodiment of the present invention provides an image display system including an image forming apparatus; and a remote image display apparatus including a remote display unit configured to display a display image output from the image forming apparatus; wherein the image forming apparatus includes an image-forming-side communication unit configured to communicate with the remote image display apparatus, a remote display unit information obtaining unit configured to obtain remote display unit information regarding the remote display unit via the image-forming-side communication unit, and a remote display image generating unit configured to generate the display image to be displayed on the remote display unit based on the remote display unit information obtained by the remote display unit information obtaining unit; and the remote image display apparatus further includes a remote-display-side communication unit configured to communicate with the image forming apparatus, a remote display unit information retaining unit configured to retain the remote display unit information regarding the remote display unit, and a remote display unit information output unit configured to output the remote display unit information retained by the remote display unit information retaining unit; wherein the remote display unit information includes resolution of the remote display unit or a number of colors displayable by the remote display unit.

Another embodiment of the present invention provides an image forming method including a display unit information obtaining step of obtaining display unit information regarding a display unit; and a display image generating step of generating a display image to be displayed on the display unit based on the display unit information obtained by the display unit information obtaining step.

Another embodiment of the present invention provides an image forming method including a communication step of communicating with a remote display unit; a remote display unit information obtaining step of obtaining remote display unit information regarding the remote display unit through the communication step; and a remote display image generating step of generating a display image to be displayed on the remote display unit based on the remote display unit information obtained by the remote display unit information obtaining step. Another embodiment of the present invention provides an image display method including a display step of displaying a display image output from an image forming apparatus on a display unit; a communication step of communicating with the image forming apparatus; a display unit information retaining step of retaining display unit information regarding the display unit; and a display unit information output step of outputting, through the communication step, the display unit information retained by the display unit information retaining step; wherein the display unit information includes resolution of the display unit or a number of colors displayable by the display unit.

Still another embodiment of the present invention provides an image display method including a remote display unit information retaining step of retaining remote display unit information regarding a remote display unit; a remote display unit information output step of outputting the remote display unit information retained by the remote display unit information retaining step; a remote display unit information obtaining step of obtaining the remote display unit information regarding the remote display unit; a remote display image generating step of generating a display image to be displayed on the remote display unit based on the remote display unit information obtained by the remote display unit information obtaining step; and a remote image display step of displaying the display image on the remote display unit; wherein the remote display unit information includes resolution of the remote display unit or a number of colors displayable by the remote display unit.

### BRIEF DESCRIPTION OF THE DRAWINGS

FIG. 1 is a drawing illustrating an exemplary image display system including an exemplary image forming apparatus according to an embodiment of the present invention;

FIG. 2 is a drawing illustrating exemplary functional configurations of the exemplary image forming apparatus and other apparatuses connected to the exemplary image forming apparatus;

FIG. 3 is a block diagram illustrating an exemplary controller unit of the exemplary image forming apparatus;

FIG. 4 is a drawing illustrating an exemplary process performed by the exemplary controller unit of the exemplary image forming apparatus;

FIG. 5 is a drawing illustrating an exemplary image display processing unit of the exemplary image forming apparatus;

FIG. 6 is a drawing illustrating an exemplary process of generating and displaying a preview image according to display unit information;

FIG. 7 is a drawing illustrating an exemplary process of obtaining display unit identification information;

FIG. 8 is a drawing illustrating an exemplary process of obtaining display unit information based on display unit identification information;

FIG. 9 is a drawing illustrating an exemplary process of obtaining display unit information from an external server;

FIG. 10 is a drawing illustrating an exemplary process of generating a preview image according to communication status;

FIG. 11 is a block diagram illustrating an exemplary configuration of a computer for implementing an image forming method according to an embodiment of the present invention; and

FIGS. 12A through 12C are exemplary tables showing specifications of image display apparatuses and the corresponding data sizes of a preview image.

### DESCRIPTION OF THE PREFERRED EMBODIMENTS

Preferred embodiments of the present invention are described below with reference to the accompanying drawings.

In the descriptions below, a multifunction printer is used as an example of an image forming apparatus. However, embodiments of the present invention may be applied to any other image forming apparatus configured to be able to display a preview image (display image) of image data to be processed, on display apparatuses having different capabilities or specifications and connected in different manners.

### First Embodiment

[Outline of Image Display System]

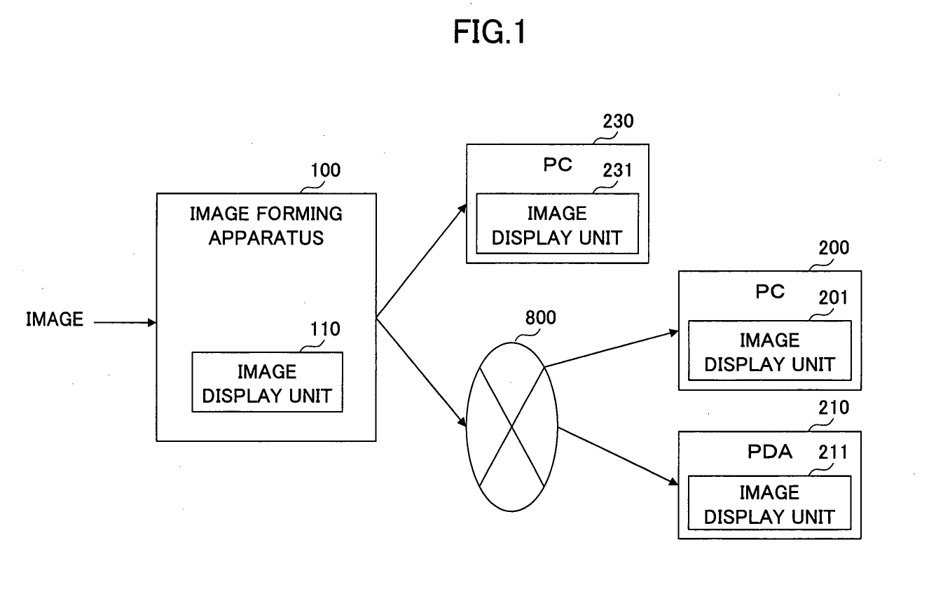

FIG. 1 is a drawing illustrating an exemplary image display system including an exemplary image forming apparatus according to an embodiment of the present invention. In the exemplary image display system shown in FIG. 1, a preview image (display image) of an image input into an image forming apparatus 100 is displayed, before the image is processed and output from the image forming apparatus 100, on an image display unit of an apparatus from which a command for processing the image is issued.

As shown in FIG. 1, the exemplary image display system includes the image forming apparatus 100, personal computers 200 and 230, and a PDA 210. The image forming apparatus 100, the personal computer 200, and the PDA 210 are connected via a network 800. The image forming apparatus 100 includes an image display unit 110, the personal computer 200 includes an image display unit 201, the personal computer 230 includes an image display unit 231, and the PDA 210 includes an image display unit 211. The PDA 210 may be a mobile phone.

[Functional Configurations of Apparatuses Connected to Image Forming Apparatus]

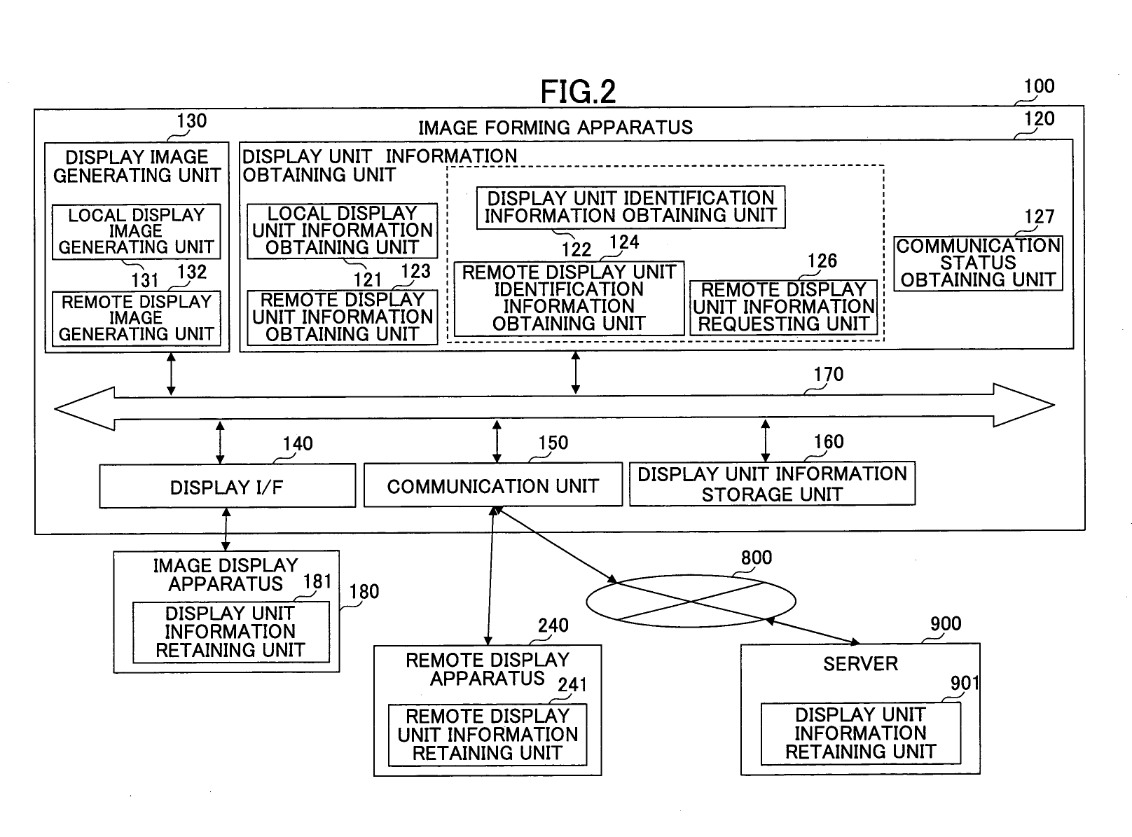

FIG. 2 is a drawing illustrating exemplary functional configurations of the image forming apparatus 100 and other apparatuses connected to the image forming apparatus 100. As shown in FIG. 2, the image forming apparatus 100 is connected directly or via the network 800 to an image display apparatus 180, a remote image display apparatus 240, and a server 900. To facilitate understanding of this embodiment, configurations of the image display apparatus 180, the remote image display apparatus 240, and the server 900 are described prior to the descriptions of the image forming apparatus 100.

The image display apparatus 180 is directly connected to the image forming apparatus 100 and is an operations panel of the image forming apparatus 100. Instead, the image display apparatus 180 may be implemented as a monitor for displaying a preview image of an image to be processed by the image forming apparatus 100.

The image display apparatus 180 includes a display unit information retaining unit 181. The display unit information retaining unit 181 retains the display unit information about the capabilities or specifications such as the resolution and the number of displayable colors of the image display apparatus 180, and/or the identification information (display unit identification information) of the image display apparatus 180. The display unit identification information is, for example, the product name or the model number of the image display apparatus 180.

The remote image display apparatus 240 is connected via, for example, a serial bus to the image forming apparatus 100. Instead, the remote image display apparatus 240 may be connected via the network 800 to the image forming apparatus 100. The remote image display apparatus 240 is, for example, a personal computer, a PDA, or a mobile phone.

The remote image display apparatus 240 includes a remote display unit information retaining unit 241. The remote display unit information retaining unit 241 retains the display unit information about the capabilities or specifications such as the resolution and the number of displayable colors of the remote image display apparatus 240, and/or the identification information (display unit identification information) of the remote image display apparatus 240. The display unit identification information is, for example, the product name or the model number of the remote image display apparatus 240.

The server 900 is connected via the network 800 to the image forming apparatus 100 and includes a display unit information retaining unit 901. The display unit information retaining unit 901 retains display unit identification information of image display apparatuses and display unit information of those image display apparatuses. The image display unit information and the display unit identification information are related to each other in the server 900. When receiving a request for the display unit information of an image display apparatus together with display unit identification information, the server 900 outputs the display unit information of the image display apparatus corresponding to the display unit identification information to a requester.

[Functional Configuration of Image Forming Apparatus]

An exemplary functional configuration of the image forming apparatus 100 according to an embodiment of the present invention is described below. The image forming apparatus 100 includes a display unit information obtaining unit 120, a display image generating unit 130, a display I/F 140, a communication unit 150, and a display unit information storage unit 160 that are connected via a local bus 170. The display I/F 140 connects the image forming apparatus 100 and the image display apparatus 180. The communication unit 150 is used for communication between the image forming apparatus 100, and the remote image display apparatus 240 and the server 900.

The display unit information storage unit 160 stores display unit identification information and display unit information that are related to each other. The display unit identification information stored in the display unit information storage unit 160 is that of the image display apparatus 180 connected to the image forming apparatus 100. The display unit information storage unit 160 may also store the display unit identification information and the display unit information of the remote image display apparatus 240. An image forming apparatus with the above configuration makes it possible to output an appropriate preview image to any one of general purpose image display apparatuses.

The display unit information obtaining unit 120 obtains the display unit information of image display apparatuses connected to the image forming apparatus 100 and communication status between the image forming apparatus 100 and the image display apparatuses. The display unit information obtaining unit 120 includes a local display unit information obtaining unit 121, a remote display unit information obtaining unit 123, a display unit identification information obtaining unit 122, a remote display unit identification information obtaining unit 124, a remote display unit information requesting unit 126, and a communication status obtaining unit 127.

The display unit information obtained by the display unit information obtaining unit 120 includes, for example, the resolution, the number of displayable colors, and information on an image decoding unit of an image display apparatus. The display unit information obtaining unit 120 also obtains communication status such as the communication speed between the image forming apparatus 100 and an image display apparatus.

The local display unit information obtaining unit 121 obtains the display unit information of the image display apparatus 180 connected directly to the image forming apparatus 100. The remote display unit information obtaining unit 123 obtains the display unit information of the remote image display apparatus 240 connected to the image forming apparatus 100 via a serial bus or the network 800.

The display unit identification information obtaining unit 122, the remote display unit identification information obtaining unit 124, and the remote display unit information requesting unit 126 obtain display unit identification information of image display apparatuses.

The display unit identification information obtaining unit 122 obtains the display unit identification information of the image display apparatus 180, and the remote display unit identification information obtaining unit 124 obtains the display unit identification information of the remote image display apparatus 240. More specifically, the display unit identification information obtaining unit 122 sends a request to the image display apparatus 180 and thereby obtains the display unit identification information, and the remote display unit identification information obtaining unit 124 sends a request to the remote image display apparatus 240 and thereby obtains the display unit identification information.

The local display unit information obtaining unit 121 may be configured to obtain the display unit information of the image display apparatus 180 from the display unit information storage unit 160 based on the display unit identification information obtained by the display unit identification information obtaining unit 122. This configuration makes it possible for an image forming apparatus to output an appropriate preview image to any one of multiple operations panels. For example, the image forming apparatus 100 may be configured to store the display unit information of multiple operations panels in the display unit information storage unit 160, to select the display unit information corresponding to one of the operations panels that is connected, and to generate a preview image based on the selected display unit information.

The remote display unit information requesting unit 126 sends the display unit identification information of the remote image display apparatus 240 obtained by the remote display unit identification information obtaining unit 124 via the communication unit 150 to the server 900 and thereby obtains the display unit information of the remote image display apparatus 240 from the server 900.

The communication status obtaining unit 127 obtains the status of communication being performed by the communication unit 150. The information on the communication status obtained by the communication status obtaining unit 127 includes, for example, a method of communication such as a LAN, IEEE 802.11, or a serial bus or the speed of a communication line. Thus, the communication status obtaining unit 127 enables the image forming apparatus 100 to generate a preview image corresponding to the communication status.

The display image generating unit 130 generates a preview image based on the display unit information obtained by the display unit information obtaining unit 120 and the communication status obtained by the communication status obtaining unit 127. The display image generating unit 130 includes a local display image generating unit 131 and a remote display image generating unit 132. The local display image generating unit 131 generates a preview image to be displayed on the image display apparatus 180, and the remote display image generating unit 132 generates a preview image to be displayed on the remote image display apparatus 240.

The local bus 170 is used for communications inside of the image forming apparatus 100. The image forming apparatus 100 may also be configured to include multiple buses for internal communication.

### Second Embodiment

[Configuration of Controller Unit of Image Forming Apparatus]

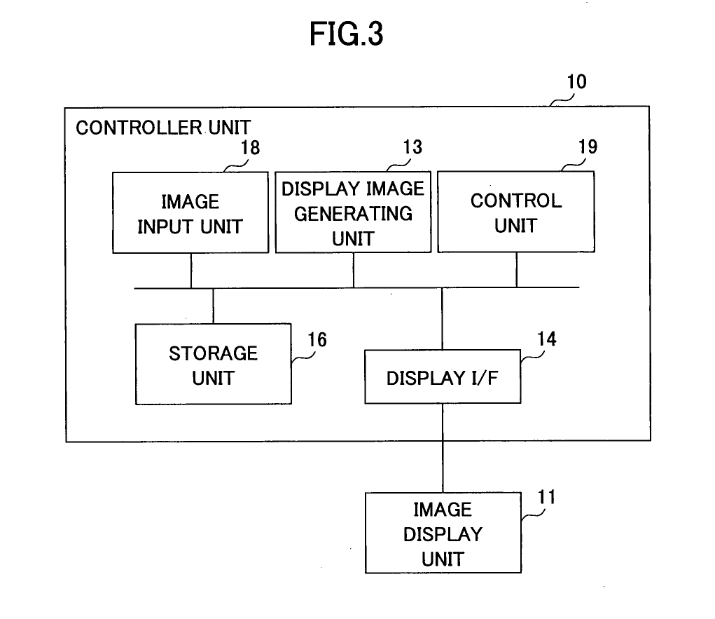

FIG. 3 is a block diagram illustrating an exemplary controller unit of the image forming apparatus 100. As shown in FIG. 3, a controller unit 10 is connected to an image display unit 11. The controller unit 10 includes a control unit 19, an image input unit 18, a display image generating unit 13, a storage unit 16, and a display I/F 14.

The control unit 19 controls other units in the controller unit 10. The image input unit 18 processes an image input from, for example, a device such as a scanner or a storage device provided in the image forming apparatus 100 or an apparatus connected via a network to the image forming apparatus 100. The storage unit 16 stores, for example, temporary data used by the control unit 19 during its processing and image data to be processed. The display I/F 14 connects the controller unit 10 and the image display unit 11.

The display image generating unit 13 generates an appropriate preview image (display image) to be displayed on the image display unit 11 according to the capabilities or specifications of the image display unit 11.

The image display unit 11 is, for example, an operations panel provided as a part of the image forming apparatus 100. The controller unit 10 outputs a preview image suitable for the image display unit 11.

[Exemplary Process Performed By Controller Unit]

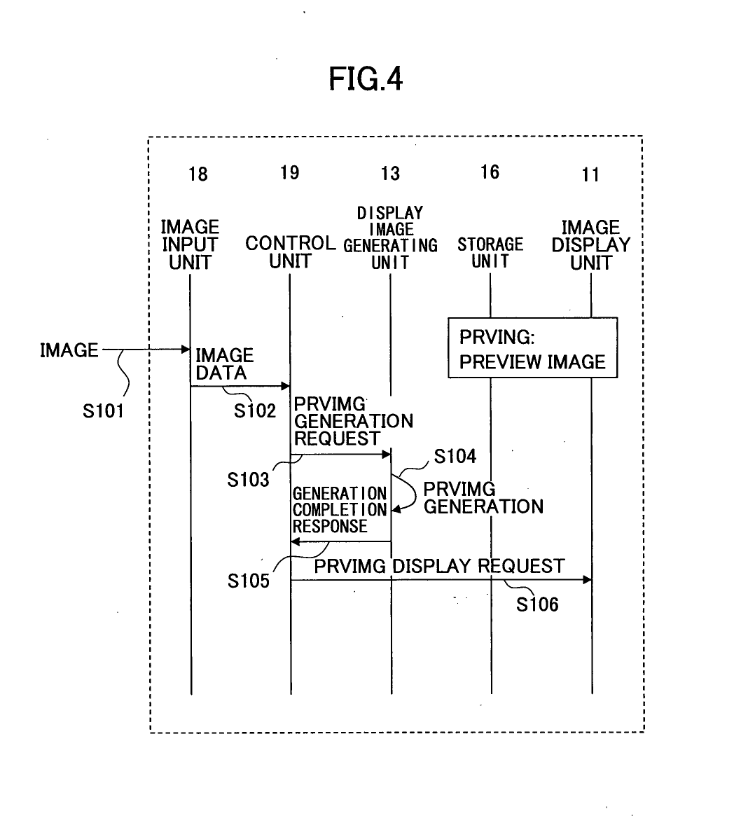

FIG. 4 is a drawing illustrating an exemplary process performed by the controller unit 10 of the image forming apparatus 100. In the exemplary process shown in FIG. 4, an image to be displayed on the image display unit 11 is generated from an input image. In step S101, an image is input as image data into the image input unit 18 of the controller unit 10. In step S102, the image input unit 18 sends the image data to the control unit 19. In step S103, the control unit 19 sends the image data and a request to generate a preview image to the display image generating unit 13.

In step S104, the display image generating unit 13 generates a preview image according to the capabilities or specifications of the image display unit 11. More specifically, the display image generating unit 13 changes the resolution or the number of colors of the image data so that the image data conform to the capabilities or specifications of the image display unit 11. The number of colors may be changed by, for example, reducing the number of bits representing each pixel in the image data, converting the image data into grayscale image data, or converting the image data into binary image data.

In step S105, the display image generating unit 13 sends a generation completion response indicating the completion of preview image generation to the control unit 19. In step S106, the control unit 19 sends a request to display the preview image generated in step S104 to the image display unit 11.

Also, the controller unit 10 may be configured to temporarily store the image input in step S101 in the storage unit 16 during steps S101 through S106. This configuration makes it possible to start generating a preview image and displaying the generated preview image before the input of other images is completed and thereby makes it possible to reduce the time necessary to display the preview image.

### Third Embodiment

[Configuration of Image Display Processing Unit of Image Forming Apparatus]

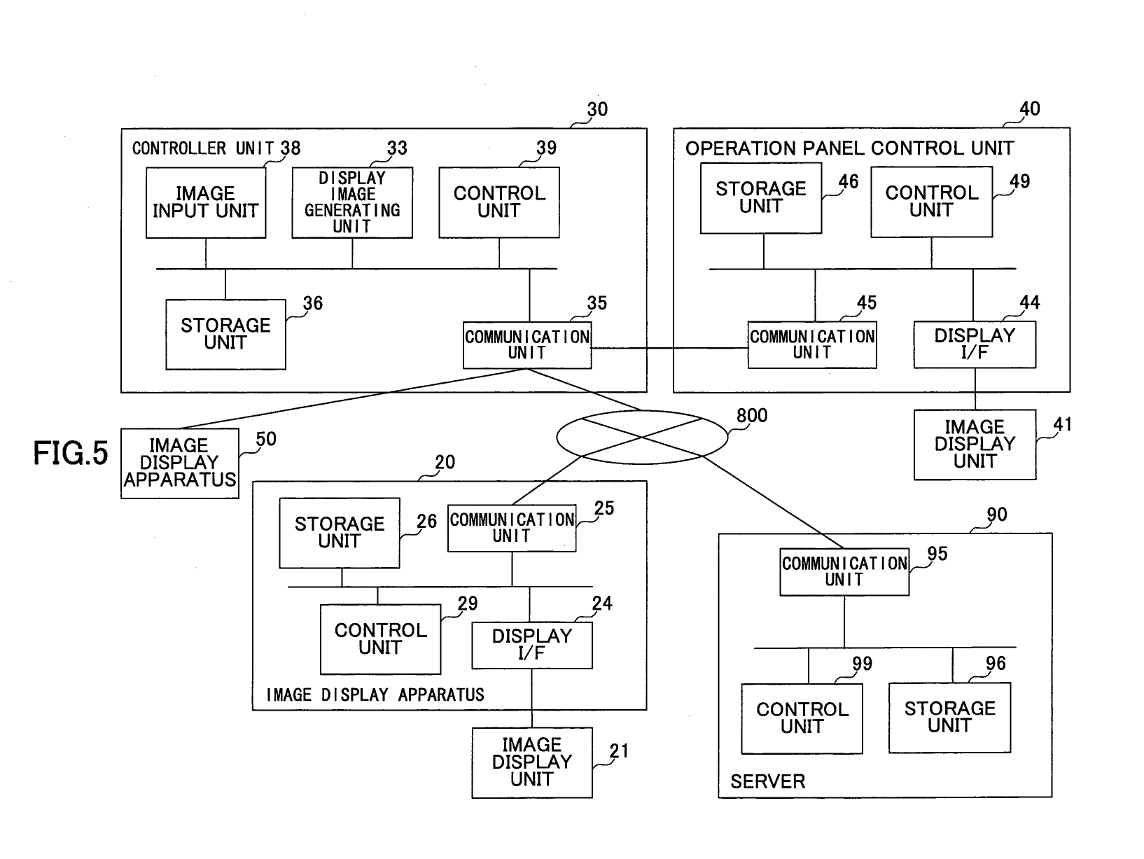

FIG. 5 is a drawing illustrating an exemplary image display processing unit of the image forming apparatus 100. As shown in FIG. 5, the image display processing unit of the image forming apparatus 100 includes a controller unit 30 and an operations panel control unit 40. With this configuration, for example, the control of processes involving handling of large-size image data and the control of other image display processes can be separately assigned to the controller unit 30 and the operations panel control unit 40. Accordingly, the above configuration improves the efficiency of image display processes performed by the image forming apparatus 100.

The image forming apparatus 100 is connected to an image display apparatus 20 and a server 90 via the network 800 and to an image display apparatus 50 via, for example, a serial bus. The operations panel control unit 40 is connected to an image display unit 41 implemented, for example, as an operations panel.

The controller unit 30 includes a control unit 39, an image input unit 38, a display image generating unit 33, a storage unit 36, and a communication unit 35.

The control unit 39 controls other units in the controller unit 30. The image input unit 38 processes an image input from, for example, a device such as a scanner or a storage device provided in the image forming apparatus 100 or an apparatus connected via a network to the image forming apparatus 100. The storage unit 36 stores, for example, temporary data used by the control unit 39 during its processing and image data to be processed. The storage unit 36 may also be used to store display unit information of image display apparatuses. Also, the display unit information may be stored in another storage device of the image forming apparatus 100 or an apparatus connected to the image forming apparatus 100.

The display image generating unit 33 generates a preview image (display image) of an image to be output according to the capabilities or specifications of an image display unit. The communication unit 35 is used for communication between the controller unit 30 and other units of the image forming apparatus 100 and for communication between the controller unit 30 and apparatuses connected to the image forming apparatus 100.

The operations panel control unit 40 controls the process of displaying an image on the operations panel 41 and includes a control unit 49, a storage unit 46, a communication unit 45, and a display I/F 44.

The control unit 49 controls other units in the operations panel control unit 40. The storage unit 46 stores, for example, temporary data used by the control unit 49 during its processing and image data to be processed. The storage unit 46 may also be used to store the display unit information of the image display unit 41.

The communication unit 45 receives, from the controller unit 30, image data to be displayed on the image display unit 41 and sends/receives other signals to/from the controller unit 30. The display I/F 44 connects the operations panel control unit 40 and the image display unit 41.

The image display unit 41 is a display unit provided as a part of the image forming apparatus 100.

The image display apparatus 20 is connected via the network 800 to the image forming apparatus 100 and includes a control unit 29, a storage unit 26, a communication unit 25, and a display I/F 24. Also, an image display unit 21 is connected to the image display apparatus 20.

The control unit 29 controls other units of the image display apparatus 20. The storage unit 26 stores, for example, temporary data used by the control unit 29 during its processing and image data to be processed. The storage unit 26 may also be used to store the display unit information of the image display unit 21. The communication unit 25 is used for communication between the image display apparatus 20 and the image forming apparatus 100 connected via the network 800. The display I/F 24 connects the image display apparatus 20 and the image display unit 21.

The image display unit 21 is a display unit provided as a part of the image display apparatus 20.

The image display apparatus 50 is connected to the communication unit 35 of the controller unit 30 by means other than the network 800. The functions and configuration of the image display apparatus 50 are substantially the same as those of the image display apparatus 20. Therefore, detailed descriptions of the image display apparatus 50 are omitted here.

The server 90 is connected via the network 800 to the image forming apparatus 100 and includes a control unit 99, a storage unit 96, and a communication unit 95. The control unit 99 controls other units of the server 90. The communication unit 95 is used for communication between the server 90 and other apparatuses in the network 800. The storage unit 96 stores display unit identification information and display unit information that are related to each other.

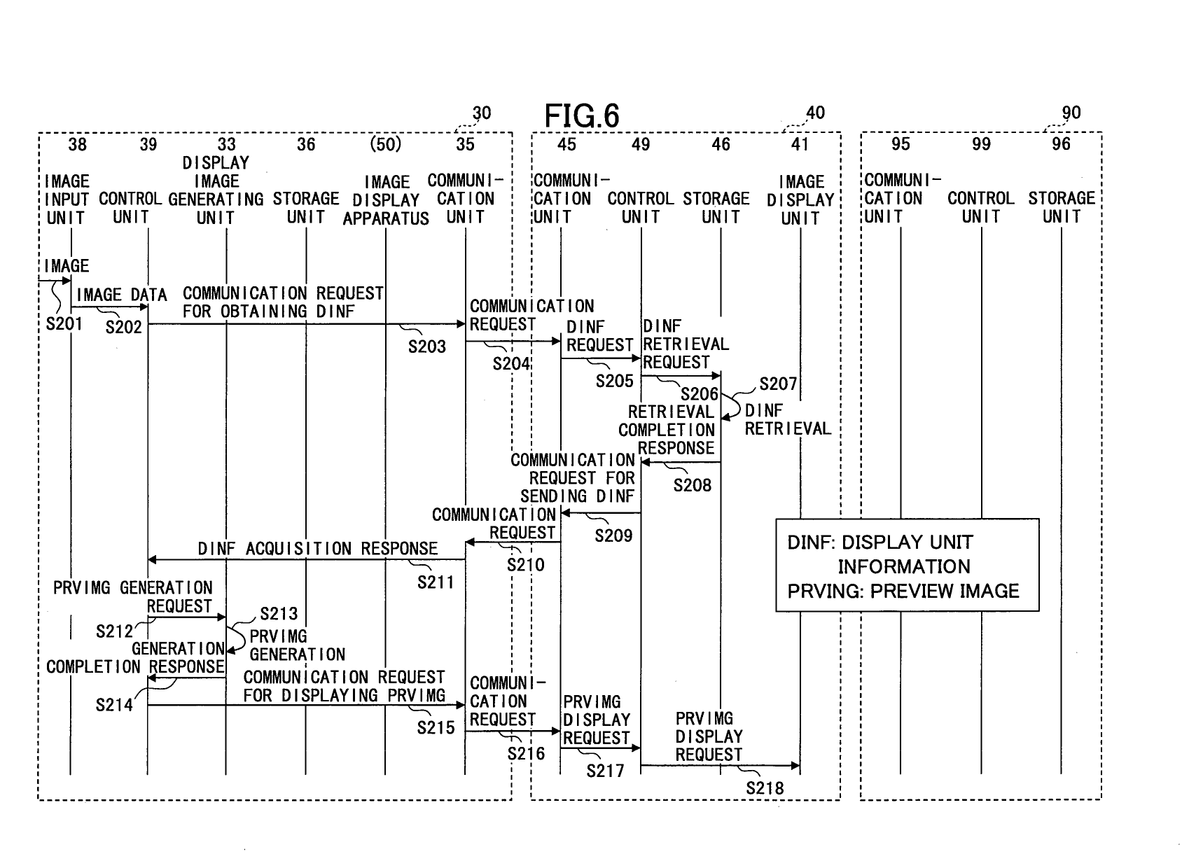

FIGS. 6 through 10 are sequence charts showing exemplary processes of displaying a preview image performed by the image forming apparatus 100. More specifically, FIGS. 6 through 10 show exemplary processes of displaying a preview image on the image display unit 41 connected to the operations panel control unit 40. However, since the operations panel control unit 40 and the image display apparatus 20 have substantially the same configuration as shown in FIG. 5, it is obvious that the exemplary processes shown in FIGS. 6 through 10 can be applied to a case where a preview image is displayed on the image display unit 21 of the image display apparatus 20.

[Exemplary Process of Generating Preview Image According to Display Unit Information]

FIG. 6 is a sequence chart showing an exemplary process, performed by the image forming apparatus 100, of generating and displaying a preview image (display image) according to display unit information obtained from the operations panel control unit 40.

In step S201 shown in FIG. 6, an image is input as image data into the image input unit 38 of the controller unit 30. In step S202, the image input unit 38 sends the image data to the control unit 39. In step S203, the control unit 39 sends the communication unit 35 a request for communication to obtain the display unit information of the image display unit 41 which display unit information is stored in the operations panel control unit 40.

In step S204, the communication unit 35 sends a request for communication to the communication unit 45 of the operations panel control unit 40. In step S205, the communication unit 45 sends a request for the display unit information to the control unit 49.

In step S206, the control unit 49 sends a request to retrieve the display unit information to the storage unit 46. In step S207, the storage unit 46 retrieves the requested display unit information. In step S208, the storage unit 46 sends a retrieval completion response together with the retrieved display unit information to the control unit 49.

In step S209, the control unit 49 sends the communication unit 45 a request for communication to send the display unit information to the controller unit 30. In step S210, the communication unit 45 sends a request for communication to the communication unit 35 of the controller unit 30. In step S211, the communication unit 35 sends an acquisition response together with the display unit information to the control unit 39.

In step S212, the control unit 39 sends the display image generating unit 33 the display unit information, the image data, and a request to generate a preview image.

In step S213, the display image generating unit 33 generates a preview image from the image data according to the display unit information. For example, the display image generating unit 33 generates the preview image by reducing the resolution of the image data to a level displayable by the image display unit 41 according to the capabilities or specifications of the image display unit 41 described in the display unit information. As other examples, the display image generating unit 33 may generate the preview image by reducing the number of bits representing each pixel in the image data and thereby reducing the number of colors of the image data, by converting the image data into grayscale image data, or by converting the image data into binary image data.

In step S214, the display image generating unit 33 sends a generation completion response indicating the completion of preview image generation to the control unit 39.

In step S215, the control unit 39 sends the communication unit 35 the generated preview image and a request for communication to send the generated preview image to the operations panel control unit 40. In step S216, the communication unit 35 sends the preview image and a request for communication to the communication unit 45 of the operations panel control unit 40.

In step S217, the communication unit 45 sends a request to display the preview image to the control unit 49. In step S218, the control unit 49 sends the preview image and a request to display the preview image to the image display unit 41. As a result, the preview image is displayed on the image display unit 41.

Also, the controller unit 30 may be configured to temporarily store the image input in step S201 in the storage unit 36 during steps S201 through S218. This configuration makes it possible to start generating a preview image and displaying the generated preview image before the input of other images is completed and thereby makes it possible to reduce the time necessary to display the preview image.

Also, when the resolution of the input image is already lower than that described in the display unit information received by the control unit 39 in step S211, steps S212 through S214 may be omitted to reduce the time necessary to display the preview image. In the above example, the controller unit 30 and the operations panel control unit 40 of the image forming apparatus 100 are configured to display a preview image on the image display unit 41. However, steps S203 through S211 can be applied to a case where an image forming apparatus supports multiple image display units having different capabilities as well as a case where an image forming apparatus supports one image display unit. In other words, the above embodiment makes it possible to use substantially the same process sequence for both of the cases and thereby makes it possible to reduce the time and costs for developing and producing an image forming apparatus.

[Exemplary Process of Obtaining Display Unit Identification Information]

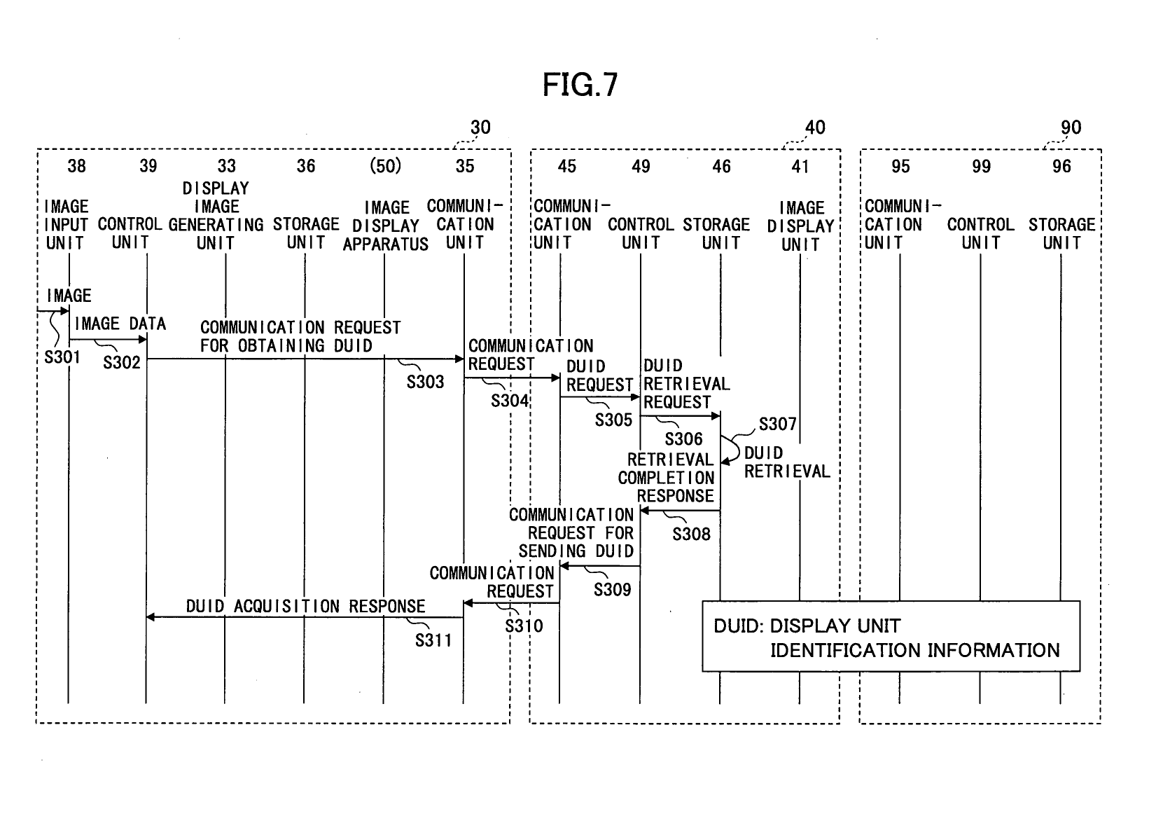

FIG. 7 is a sequence chart showing an exemplary process, performed by the image forming apparatus 100, of obtaining display unit identification information from the operations panel control unit 40.

In step S301 shown in FIG. 7, an image is input as image data into the image input unit 38 of the controller unit 30. In step S302, the image input unit 38 sends the image data to the control unit 39. In step S303, the control unit 39 sends a request for communication to obtain display unit identification information to the communication unit 35.

In step S304, the communication unit 35 sends a request for communication to the communication unit 45 of the operations panel control unit 40. In step S305, the communication unit 45 sends a request for the display unit identification information to the control unit 49.

In step S306, the control unit 49 sends a request to retrieve the display unit identification information to the storage unit 46. In step S307, the storage unit 46 retrieves the requested display unit identification information. In step S308, the storage unit 46 sends a retrieval completion response together with the retrieved display unit identification information to the control unit 49.

In step S309, the control unit 49 sends the communication unit 45 the display unit identification information and a request for communication to send the display unit information to the controller unit 30. In step S310, the communication unit 45 sends a request for communication to the communication unit 35 of the controller unit 30. In step S311, the communication unit 35 sends an acquisition response together with the display unit identification information to the control unit 39.

As described above, steps S303 through S306 are designed to obtain display unit identification information. However, steps S303 through S306 may be designed to obtain display unit information when it is not known whether the information stored in the operations panel control unit 40 is display unit identification information or display unit information. In this case, in step S307, the storage unit 46 retrieves display unit information instead of display unit identification information and the retrieved display unit information is sent to the controller 30. When the display unit information is received in step S311, the control unit 39 of the controller unit 30 generates a preview image (display image) according to the display unit information by steps S212 through S218 shown in FIG. 6. This configuration makes it possible to use substantially the same process sequence regardless of whether the operations panel control unit 40 retains display unit information or display unit identification information.

[Exemplary Process of Obtaining Display Unit Information Based on Display Unit Identification Information]

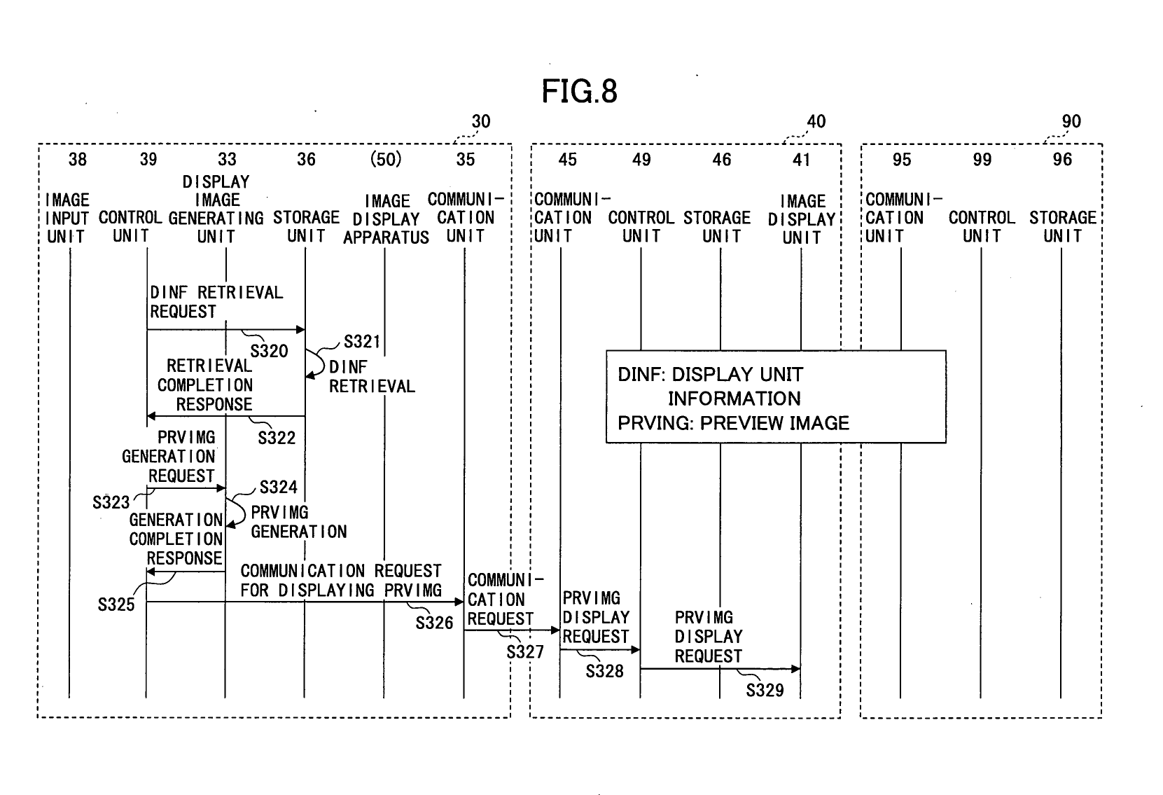

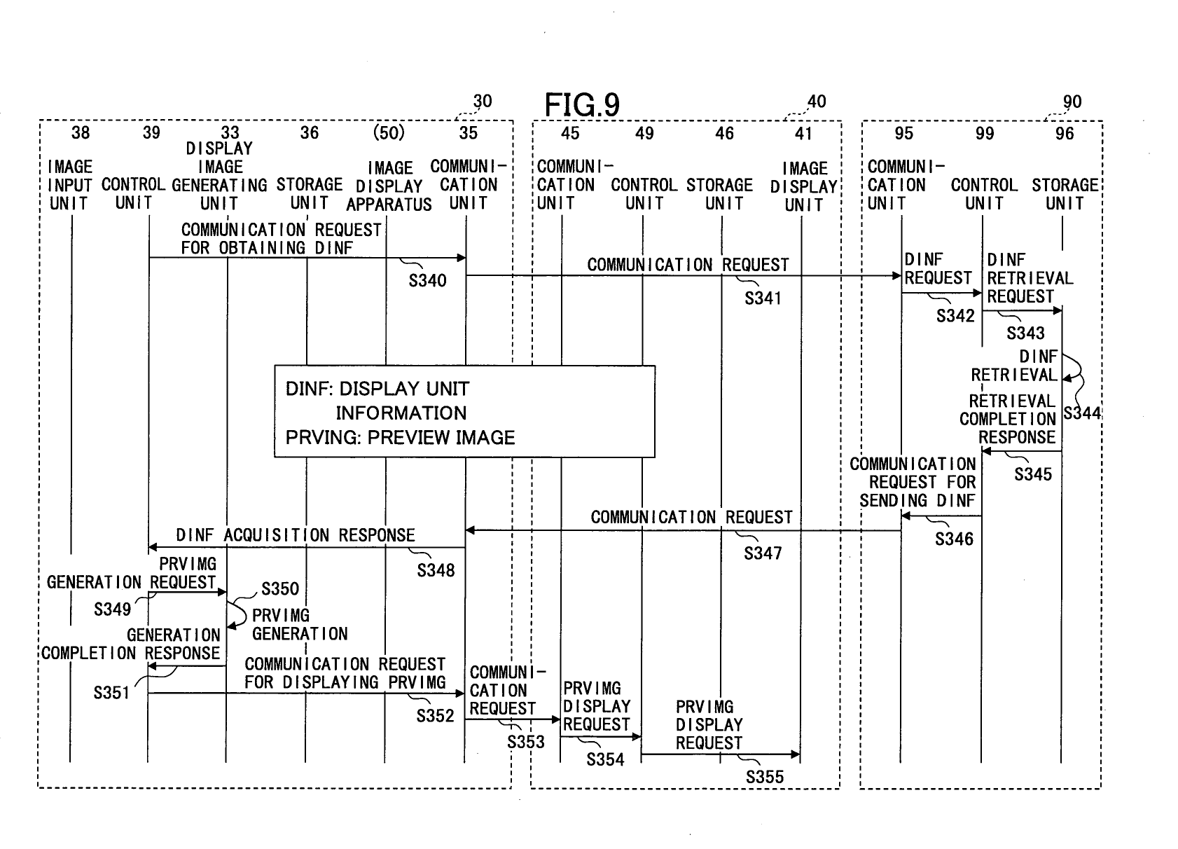

FIGS. 8 and 9 are sequence charts showing exemplary processes, performed by the image forming apparatus 100, of generating and displaying a preview image (display image) based on display unit information corresponding to display unit identification information. FIG. 8 shows a case where the display unit information corresponding to the display unit identification information is retained in the image forming apparatus 100. FIG. 9 shows a case where the display unit information corresponding to the display unit identification information is retained in the server 90 connected to the image forming apparatus 100.

When the capabilities or specifications of operations panels connected to the image forming apparatus 100 are predetermined, the display unit information of those operations panels may be stored in the image forming apparatus 100. With the stored display unit information, the image forming apparatus 100 can generate an appropriate preview image for any one of the operations panels.

Step S320 shown in FIG. 8 is performed following step S311 shown in FIG. 7. In step S320, the control unit 39 sends the storage unit 36 a request to retrieve display unit information corresponding to the obtained display unit identification information. In step S321, the storage unit 36 retrieves the display unit information corresponding to the display unit identification information. In step S322, the storage unit 36 sends a retrieval completion response together with the retrieved display unit information to the control unit 39.

Steps S323 through S329 are substantially the same as steps S212 through S218 shown in FIG. 6 and therefore descriptions of those steps are omitted here.

The controller unit 30 may also be configured to temporarily store the image input in step S301 in the storage unit 36 during steps S301 through S329. This configuration makes it possible to start generating a preview image and displaying the generated preview image before the input of other images is completed and thereby makes it possible to reduce the time necessary to display the preview image. Also, in this case, display unit identification information and display unit information may be stored in a storage unit other than the storage unit 36. In other words, the controller unit 30 may be configured to include a storage unit for storing display unit information and display unit identification information and a storage unit used as a working memory for storing images. This configuration makes it easier to upgrade the controller unit 30.

Further, when a preview image is to be displayed on an external image display apparatus such as the image display apparatus 20 connected to the image forming apparatus 100 and when the image display apparatus includes an image decoding unit, the display image generating unit 33 (or an image encoding unit of the display image generating unit 33) may encode the preview image in step S324 with an encoding method corresponding to the information on the image decoding unit described in the display unit information. This makes it possible to reduce the size of image data transmitted between the image forming apparatus 100 and an image display apparatus and thereby to reduce the time necessary to display a preview image.

[Exemplary Process of Obtaining Display Unit Information From Server Based on Display Unit Identification Information]

FIG. 9 is a sequence chart showing an exemplary process of obtaining display unit information corresponding to display unit identification information from the server 90 connected via the network 800 to the image forming apparatus 100. In this case, the server 90 retains the display unit information containing capabilities and specifications of various image display apparatuses connected to the image forming apparatus 100. The image forming apparatus 100 obtains the display unit information of an image display apparatus from the server 90 and thereby generates an appropriate preview image for the image display apparatus. This configuration eliminates the need to store display unit information in the image forming apparatus 100.

Step S340 shown in FIG. 9 is performed following step S311 shown in FIG. 7. Also, step S340 may be performed following step S322 shown in FIG. 8 when the display unit information corresponding to the display unit identification information cannot be retrieved in step S321.

In step S340, the control unit 39 sends the communication unit 35 a request for communication to obtain display unit information corresponding to the obtained display unit identification information. In step S341, the communication unit 35 sends a request for communication to the communication unit 95 of the server 90. In step S342, the communication unit 95 sends a request for the display unit information corresponding to the display unit identification information to the control unit 99.

In step S343, the control unit 99 sends a request to retrieve the display unit information corresponding to the display unit identification information to the storage unit 96. In step S344, the storage unit 96 retrieves the display unit information corresponding to the display unit identification information. In step S345, the storage unit 96 sends a retrieval completion response together with the retrieved display unit information to the control unit 99.

In step S346, the control unit 99 sends the communication unit 95 a request for communication to send the display unit information to the controller unit 30. In step S347, the communication unit 95 sends a request for communication to the communication unit 35 of the controller unit 30. In step S348, the communication unit 35 sends an acquisition response together with the display unit information to the control unit 39.

Steps S349 through S355 are substantially the same as steps S212 through S218 shown in FIG. 6 and therefore descriptions of those steps are omitted here.

The controller unit 30 may also be configured to temporarily store the image input in step S301 in the storage unit 36 during steps S301 through S355. This configuration makes it possible to start generating a preview image and displaying the generated preview image before the input of other images is completed and thereby makes it possible to reduce the time necessary to display the preview image.

Also, when a preview image is to be displayed on an external image display apparatus such as the image display apparatus 20 connected to the image forming apparatus 100 and when the image display apparatus includes an image decoding unit, the display image generating unit 33 (or an image encoding unit of the display image generating unit 33) may encode the preview image in step S350 with an encoding method corresponding to the information on the image decoding unit described in the display unit information. This makes it possible to reduce the size of image data transmitted between the image forming apparatus 100 and an image display apparatus and thereby to reduce the time necessary to display a preview image.

[Exemplary Process of Generating Preview Image According to Communication Status]

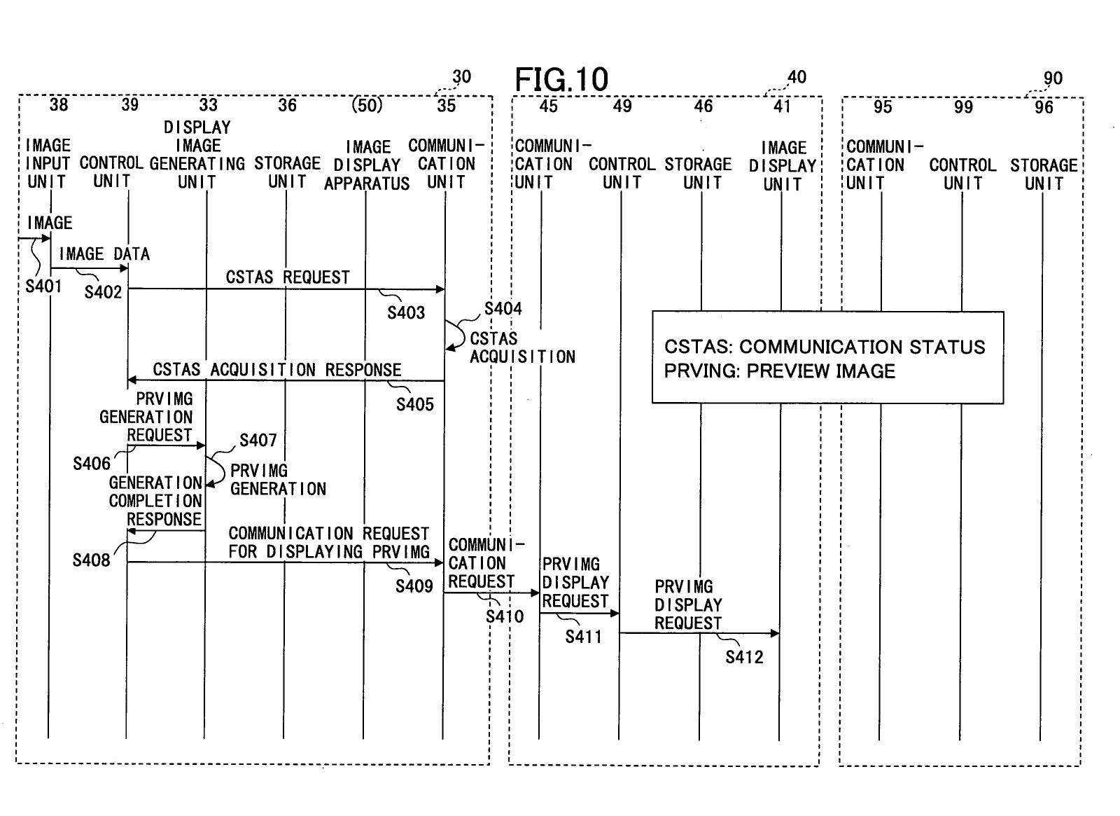

FIG. 10 is a sequence chart showing an exemplary process of generating a preview image (display image) according to the status of communication between the image forming apparatus 100 and the image display apparatus 20. In the exemplary process shown in FIG. 10, it is assumed that a preview image is displayed on the image display unit 41 connected to the operations panel control unit 40 of the image forming apparatus 100. However, the exemplary process may be applied to a case where a preview image is displayed on the image display apparatus 20.

In step S401 shown in FIG. 10, an image is input as image data into the image input unit 38 of the controller unit 10. In step S402, the image input unit 38 sends the image data to the control unit 39. In step S403, the control unit 39 sends the communication unit 35 a request to obtain information on the status of communication between the image forming apparatus 100 and the image display unit 41.

In step S404, the communication unit 35 obtains information on the status of communication with the image display unit 41. The communication status information obtained by the communication unit 35 includes, for example, the method of communication or the status of network traffic.

In step S405, the communication unit 35 sends the control unit 39 an acquisition response together with the communication status information. In step S406, the control unit 39 sends the display image generating unit 33 the image data, the communication status information, and a request to generate a preview image.

In step S407, the display image generating unit 33 generates a preview image from the image data according to the communication status information. More specifically, the display image generating unit 33 determines the data size of a preview image according to, for example, the status of network traffic in the communication status information, and generates a preview image with the determined size. Or, the display image generating unit 33 may be configured to determine the size of a preview image according to the method of communication. For example, when a wired LAN conforming to IEEE 802.3 is used, a preview image with a large data size is generated; and when a wireless LAN conforming to IEEE 802.11 is used, a preview image with a small data size is generated.

In any case, the display image generating unit 33 generates a preview image by changing the size of the image data. For example, the display image generating unit 33 reduces the size of the image data by reducing the resolution or the number of colors. Also, when a preview image is to be displayed on an external image display apparatus such as the image display apparatus 20 connected to the image forming apparatus 100 and when the image display apparatus includes an image decoding unit, the display image generating unit 33 may encode the preview image with an encoding method corresponding to the decoding method of the image decoding unit of the image display apparatus.

Steps S408 through S412 are substantially the same as steps S214 through S218 shown in FIG. 6 and therefore descriptions of those steps are omitted here.

(Exemplary Configuration of Computer for Implementing Image Forming Method According to Embodiment of the Present Invention)

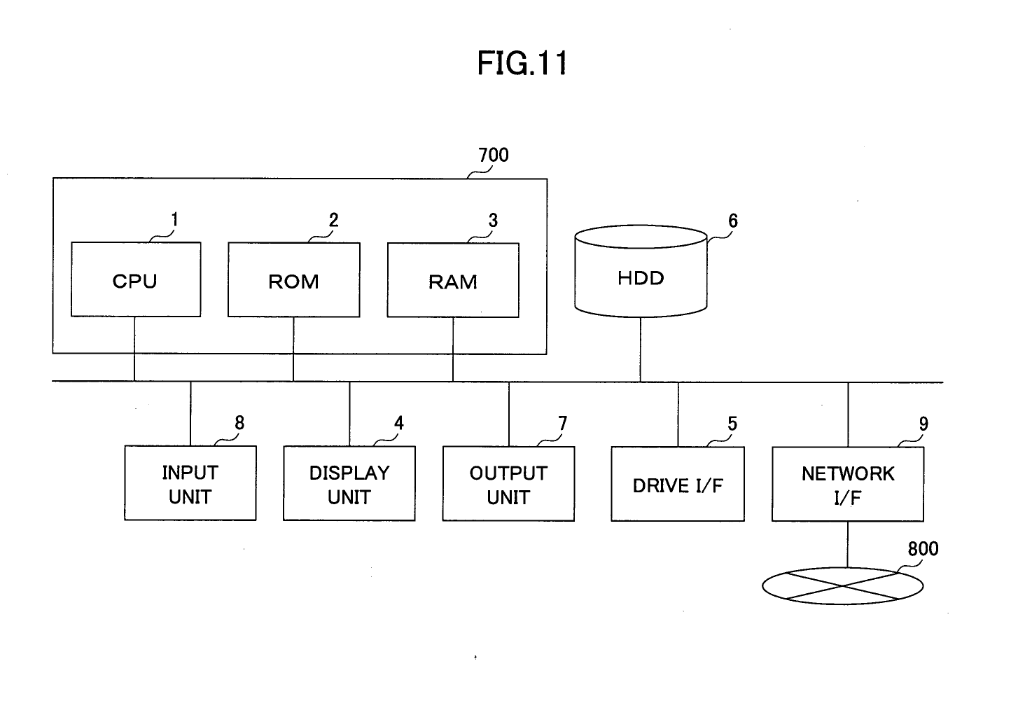

FIG. 11 is a block diagram illustrating an exemplary configuration of a computer for implementing an image forming method according to an embodiment of the present invention. A main processing unit 700 and an input unit 8 of the exemplary computer shown in FIG. 11 are used to implement an exemplary image forming method according to an embodiment of the present invention.

The exemplary computer shown in FIG. 11 includes the main processing unit 700, the input unit 8, a display unit 4, an output unit 7, a drive I/F 5, a network I/F 9, and a hard disk drive 6.

The main processing unit 700 performs the exemplary image forming method and includes a CPU 1, a ROM 2, and a RAM 3. The CPU 1 controls various processes and performs the exemplary image forming method by executing an image forming program stored, for example, in the ROM 2. The ROM 2 is a storage unit for storing various programs executed by the CPU 1. The RAM 3 is used as a working memory by the CPU 1 to perform various processes.

The input unit 8 includes devices for entering commands into the exemplary computer. The display apparatus 4 displays, for example, the status of processing. The output unit 7 forms an image generated by the main processing unit 700 on a recording medium such as paper. The drive I/F 5 is an interface for connecting a drive for reading/writing data from/to a removable medium such as a CD-ROM or a DVD. The network I/F 9 is an interface for connecting the exemplary computer to the network 800. The hard disk drive 6 is a storage unit for storing large-volume data.

An image forming program according to an embodiment of the present invention may be stored in the hard disk drive 6 instead of in the ROM 2. Also, an image forming program according to an embodiment of the present invention may be stored in a removable medium and loaded by the CPU 1 via a drive connected to the drive I/F 5.

[Relationship Between Specifications of Image Display Apparatuses and Data Sizes of Preview Image]

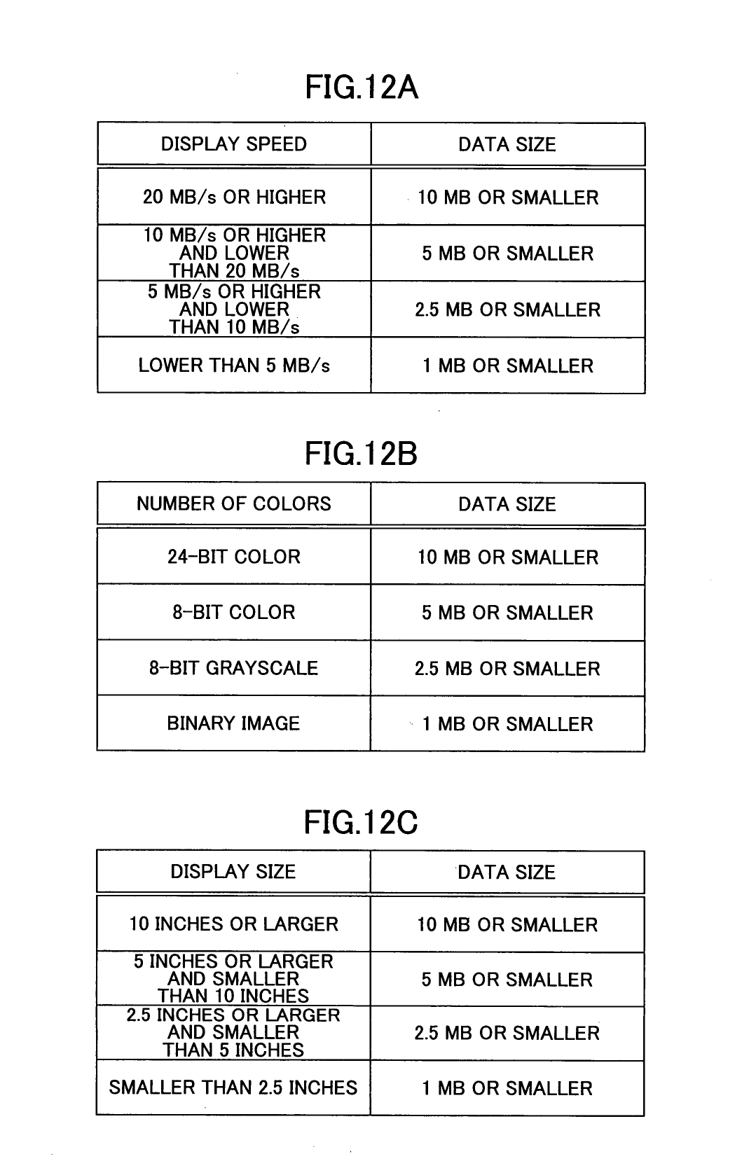

FIGS. 12A through 12C are exemplary tables showing specifications of image display apparatuses and the corresponding data sizes of a preview image (display image). The image forming apparatus 100 refers to the exemplary tables when determining the data size of a preview image. FIG. 12A is an exemplary table showing display speeds of image display apparatuses and the corresponding data sizes of a preview image. For example, when the display speed of an image display apparatus is 15 MB/s, the image forming apparatus 100 determines the number of colors, resolution, or data compression (encoding) rate of a preview image so that its data size becomes 5 MB or smaller.

FIG. 12B is an exemplary table showing the numbers of displayable colors of image display apparatuses and the corresponding data sizes of a preview image. For example, when an image display apparatus can display 8-bit color images, the image forming apparatus 100 reduces the number of bits representing each pixel in a preview image to eight or fewer and determines the resolution or data compression (encoding) rate of the preview image so that its data size becomes 5 MB or smaller.

The exemplary table shown in FIG. 12B may also be used to determine the number of colors when the data size of a preview image is determined according to the status of communication. For example, when the determined data size of a preview image is 2.5 MB or smaller, the preview image is generated as an 8-bit grayscale image.

FIG. 12C is an exemplary table showing display sizes of image display apparatuses and the corresponding data sizes of a preview image. For example, when the display size of an image display apparatus is 8 inches, the image forming apparatus 100 determines the number of colors, resolution, or data compression rate of a preview image so that its data size becomes 5 MB or smaller.

As described above, embodiments of the present invention provide an image forming apparatus that can generate an appropriate preview image of image data for any one of display apparatuses having different capabilities or specifications or connected in different manners.

An embodiment of the present invention provides an image forming apparatus that can generate a preview image according to the resolution or the number of displayable colors of an image display apparatus.

An embodiment of the present invention provides an image forming apparatus that can obtain information on the capabilities or specifications of an image display apparatus and generate a preview image according to the obtained information.

Embodiments of the present invention provide an image forming apparatus that can generate an appropriate preview image of image data for any one of remote display apparatuses having different capabilities or specifications or connected in different manners.

An embodiment of the present invention provides an image forming apparatus that can obtain information on the capabilities or specifications of a remote image display apparatus and generate a preview image according to the obtained information.

An embodiment of the present invention provides an image forming apparatus that is able to reduce the data size of a preview image by encoding the preview image with an encoding method corresponding to the decoding method of an image decoding unit of a remote image display apparatus, and thereby to reduce the time necessary to send the preview image to the remote image display apparatus.

An embodiment of the present invention provides an image forming apparatus that can generate a preview image with a data size that is suitable for the status of communication between the image forming apparatus and a remote image display apparatus.

An embodiment of the present invention provides an image display apparatus that can output information on the capabilities or specifications of the image display apparatus to an image forming apparatus.

Further, embodiments of the present invention provide an image display system including an image forming apparatus that can generate an appropriate preview image of image data for any one of remote display apparatuses having different capabilities or specifications or connected in different manners.

The present invention is not limited to the specifically disclosed embodiments, and variations and modifications may be made without departing from the scope of the present invention.

The present application is based on Japanese Priority Application No. 2006-081521, filed on Mar. 23, 2006, the entire contents of which are hereby incorporated herein by reference.

What is claimed is:

1. An image forming apparatus, comprising:
a display unit information obtaining unit configured to obtain display unit information regarding a display unit; and
a display image generating unit configured to generate a display image to be displayed on the display unit based on the display unit information obtained by the display unit information obtaining unit.

2. The image forming apparatus as claimed in claim 1, wherein
the display unit information includes resolution of the display unit or a number of colors displayable by the display unit; and
the display image generating unit is configured to generate the display image in such a manner that resolution or a number of colors of the display image becomes equal to or lower than the resolution or the number of colors included in the display unit information.

3. The image forming apparatus as claimed in claim 1, further comprising:
a display unit identification information obtaining unit configured to obtain display unit identification information that identifies the display unit, wherein the display unit information obtaining unit is configured to obtain the display unit information based on the display unit identification information obtained by the display unit identification information obtaining unit.

4. An image forming apparatus, comprising:
a communication unit configured to communicate with a remote display unit;
a remote display unit information obtaining unit configured to obtain remote display unit information regarding the remote display unit via the communication unit; and
a remote display image generating unit configured to generate a display image to be displayed on the remote display unit based on the remote display unit information obtained by the remote display unit information obtaining unit.

5. The image forming apparatus as claimed in claim 4, further comprising:
a remote display unit identification information obtaining unit configured to obtain remote display unit identification information that identifies the remote display unit; and
a remote display unit information requesting unit configured to obtain the remote display unit information corresponding to the remote display unit identification information from a server configured to relate and store the remote display unit identification information and the remote display unit information;
wherein the communication unit is configured to communicate with the server and the remote display unit information requesting unit obtains the remote display unit information via the communication unit from the server.

6. The image forming apparatus as claimed in claim 4, wherein
the remote display unit information includes an image decoding method of an image decoding unit of the remote display unit; and
the remote display image generating unit includes an image encoding unit configured to encode the display image with an encoding method corresponding to the image decoding method included in the remote display unit information.

7. The image forming apparatus as claimed in claim 4, further comprising:
a communication status obtaining unit configured to obtain status of communication between the image forming apparatus and the remote display unit, wherein the remote display image generating unit is configured to generate the display image according to the status of communication obtained by the communication status obtaining unit.

8. An image display apparatus, comprising:
a display unit configured to display a display image output from an image forming apparatus;
a communication unit configured to communicate with the image forming apparatus;
a display unit information retaining unit configured to retain display unit information regarding the display unit; and
a display unit information output unit configured to output the display unit information retained by the display unit information retaining unit;
wherein the display unit information includes resolution of the display unit or a number of colors displayable by the display unit.

9. The image display apparatus as claimed in claim 8, wherein the display unit information includes identification information of the image display apparatus.

10. The image display apparatus as claimed in claim 8, wherein the display unit information output unit is configured to output the display unit information when an output request for the display unit information is received from the image forming apparatus.

11. An image display system, comprising:
an image forming apparatus; and
a remote image display apparatus including a remote display unit configured to display a display image output from the image forming apparatus; wherein
the image forming apparatus includes
an image-forming-side communication unit configured to communicate with the remote image display apparatus,
a remote display unit information obtaining unit configured to obtain remote display unit information regarding the remote display unit via the image-forming-side communication unit, and
a remote display image generating unit configured to generate the display image to be displayed on the remote display unit based on the remote display unit information obtained by the remote display unit information obtaining unit;
the remote image display apparatus further includes
a remote-display-side communication unit configured to communicate with the image forming apparatus,
a remote display unit information retaining unit configured to retain the remote display unit information regarding the remote display unit, and
a remote display unit information output unit configured to output the remote display unit information retained by the remote display unit information retaining unit; and
the remote display unit information includes resolution of the remote display unit or a number of colors displayable by the remote display unit.

12. An image forming method, comprising:
a display unit information obtaining step of obtaining display unit information regarding a display unit; and
a display image generating step of generating a display image to be displayed on the display unit based on the display unit information obtained by the display unit information obtaining step.

13. An image forming method, comprising:
a communication step of communicating with a remote display unit;
a remote display unit information obtaining step of obtaining remote display unit information regarding the remote display unit through the communication step; and
a remote display image generating step of generating a display image to be displayed on the remote display unit based on the remote display unit information obtained by the remote display unit information obtaining step.

14. The image forming method as claimed in claim 13, further comprising:
a remote display unit identification information obtaining step of obtaining remote display unit identification information that identifies the remote display unit; and
a remote display unit information requesting step of obtaining the remote display unit information corresponding to the remote display unit identification information from a server configured to relate and store the remote display unit identification information and the remote display unit information;
wherein the communication step is a step of communicating with the server and the remote display unit information requesting step is performed through the communication step.

15. The image forming method as claimed in claim 13, wherein
the remote display unit information includes an image decoding method of an image decoding unit of the remote display unit; and
the remote display image generating step includes an image encoding step of encoding the display image with an encoding method corresponding to the image decoding method included in the remote display unit information.

16. An image display method, comprising:
a display step of displaying a display image output from an image forming apparatus on a display unit;
a communication step of communicating with the image forming apparatus;
a display unit information retaining step of retaining display unit information regarding the display unit; and
a display unit information output step of outputting, through the communication step, the display unit information retained by the display unit information retaining step;
wherein the display unit information includes resolution of the display unit or a number of colors displayable by the display unit.

17. An image display method, comprising:
a remote display unit information retaining step of retaining remote display unit information regarding a remote display unit;
a remote display unit information output step of outputting the remote display unit information retained by the remote display unit information retaining step;
a remote display unit information obtaining step of obtaining the remote display unit information regarding the remote display unit;
a remote display image generating step of generating a display image to be displayed on the remote display unit based on the remote display unit information obtained by the remote display unit information obtaining step; and
a remote image display step of displaying the display image on the remote display unit;
wherein the remote display unit information includes resolution of the remote display unit or a number of colors displayable by the remote display unit.

18. A storage medium having computer readable code embodied therein for causing a computer to perform the image forming method as claimed in claim 12.

19. A storage medium having computer readable code embodied therein for causing a computer to perform the image display method as claimed in claim 16.
